(19) United States
(12) Patent Application Publication
(10) Pub. No.: US 2024/0105571 A1
(43) Pub. Date: Mar. 28, 2024

(54) IMPLANTATION OF SPECIES ON GLASS CORE SURFACE FOR LOW LOSS AND HIGH STRENGTH APPLICATIONS

(71) Applicant: Intel Corporation, Santa Clara, CA (US)

(72) Inventors: Brandon C. MARIN, Gilbert, AZ (US); Haobo CHEN, Gilbert, AZ (US); Bai NIE, Chandler, AZ (US); Srinivas V. PIETAMBARAM, Chandler, AZ (US); Gang DUAN, Chandler, AZ (US); Jeremy D. ECTON, Gilbert, AZ (US); Suddhasattwa NAD, Chandler, AZ (US)

(21) Appl. No.: 17/954,288

(22) Filed: Sep. 27, 2022

(51) Int. Cl. H01L 23/498; H01L 21/48

(52) U.S. Cl. CPC H01L 23/49827; H01L 21/486; H01L 23/49894; H01L 23/15

(57) ABSTRACT

Embodiments disclosed herein include glass cores and methods of forming glass cores. In an embodiment, a core for an electronic package comprises a substrate with a first surface and a second surface opposite from the first surface, where the substrate comprises glass, In an embodiment, a via opening is provided through the substrate, and a diffusion layer is along the first surface, the second surface, and the via opening.

### TECHNICAL FIELD

Embodiments of the present disclosure relate to electronic packages, and more particularly to a glass core with species selectively implanted over surfaces of the glass core for low loss and high strength applications.

### BACKGROUND

As electronic packaging architectures continue to increase in complexity, it is becoming more common to use glass cores for the package substrate. Traditional low loss materials need to be reconfigured in order provide high performing through glass vias. For example, traditional glass materials may not have low enough dielectric constants in order to enable high speed IO (HSIO) applications. Additionally, the modulus of the glass may not be suitable to provide robust mechanical performance for the electronic package. Altering the bulk material of the glass cores in order to accommodate HSIO applications or more robust mechanical solutions may result in significant increases in the cost of the glass core. As such, alternative solutions may be desired.

### BRIEF DESCRIPTION OF THE DRAWINGS

FIG. 1 is a cross-sectional illustration of a core with through glass vias (TGVs) that are lined with a first diffusion layer that enables low loss TGVs, in accordance with an embodiment.

FIG. 2 is a cross-sectional illustration of a core with TGVs that are lined with a second diffusion layer that enables a higher modulus for improved mechanical reliability, in accordance with an embodiment.

FIG. 3 is a graph of the concentration gradient of a dopant into the surface of the glass core, in accordance with an embodiment.

FIG. 4A is a cross-sectional illustration of a glass core, in accordance with an embodiment.

FIG. 4B is a cross-sectional illustration of the glass core after via openings are formed through a thickness of the glass core, in accordance with an embodiment.

FIG. 4C is a cross-sectional illustration of the glass core after a dry film resist (DFR) is applied over select ones of the via openings, in accordance with an embodiment.

FIG. 4D is a cross-sectional illustration of the glass core after a diffusion layer is formed into the exposed surfaces of the glass core, in accordance with an embodiment.

FIG. 4E is a cross-sectional illustration of the glass core after the DFR is stripped, in accordance with an embodiment.

FIG. 4F is a cross-sectional illustration of the glass core after TGVs and first routing layers are provided on the glass core, in accordance with an embodiment.

FIG. 5 is a cross-sectional illustration of a computing system that includes a package substrate with a glass core that includes a selective diffusion layer, in accordance with an embodiment.

FIG. 6 is a schematic of a computing device built in accordance with an embodiment.

### EMBODIMENTS OF THE PRESENT DISCLOSURE

Described herein is a glass core with species selectively implanted over surfaces of the glass core for low loss and high strength applications, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing glass core architectures may not provide the desired electrical and/or mechanical properties needed for advanced packaging solutions. Particularly, existing bulk glass materials may not provide a low enough dielectric constant in order to enable high speed IO (HSIO) applications. Additionally, the modulus of existing bulk glass materials may not be high enough to provide robust mechanical performance. Switching the entirety of the bulk glass to more electrically and/or mechanically favorable materials is particularly cost prohibitive. This is especially true where only certain portions of the glass core need low loss or high modulus properties, and the remainder of the glass core can properly function with the material properties of existing glass core materials.

Accordingly, embodiments disclosed herein include glass cores that are selectively modified in order to locally adjust the mechanical and/or electrical properties of the glass core. In some embodiments, a diffusion layer may be formed into surfaces of the glass core. As used herein, a “diffusion layer” may refer to a region of the glass core that includes a dopant or species that is not present in the bulk of the glass core, or a dopant or species that is present at concentrations higher than the concentration of the dopant or species throughout the bulk of the glass core. In some instances, a diffusion layer may have gradient with a higher concentration closer to the surface of the glass core and a second (lower) concentration a distance away from the surface of the glass core. In an embodiment, the detectable thickness of the diffusion layer may be approximately 10 μm or less, or approximately 5 μm or less. As used herein, “approximately” may refer to a range that is within ten percent of the stated value. For example, approximately 10 μm may refer to a range between 9 μm and 11 μm. The diffusion layer may be detected using certain material composition measurement tools, such as, X-ray photoelectron spectroscopy (XPS), Raman spectroscopy, energy dispersive X-ray (EDX) spectroscopy, and the like.

In one embodiment, the dielectric constant can be locally reduced in order to enable low loss operation. Such an embodiment may be particularly useful for HSIO applications. In order to reduce the dielectric constant, a dopant, such as a borate (e.g., boron and oxygen) may be diffused into the glass core to form a borate diffusion layer. The localized concentration of borate at the surface of the glass core may account for up to approximately 20% of the total glass composition. In another embodiment, the strength (e.g., modulus) can be locally increased. In order to increase the modulus, a dopant, such as alumina (e.g., aluminum and oxygen) may be diffused into the glass core to form an alumina diffusion layer. The localized concentration of alumina at the surface of the glass core may account for up to approximately 25% of the total glass composition.

In an embodiment, the diffusion layers may be formed using any suitable diffusion process. In some embodiments an ion implantation process may be used. In such embodiments, ions may be implanted into the glass core. An annealing process may then be implemented in order to diffuse the implanted ions. In other embodiments, a heat treatment or a chemical treatment may be used in order to diffuse a given species into the surfaces of the glass core.

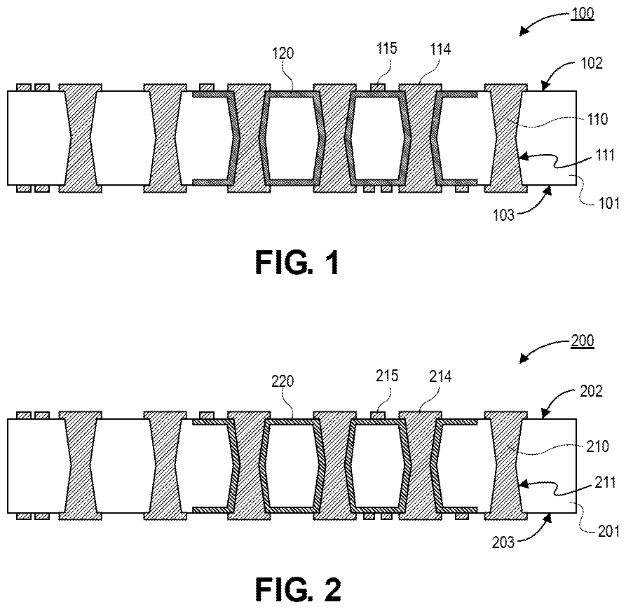

Referring now to FIG. 1, a cross-sectional illustration of a glass core 100 is shown, in accordance with an embodiment. In an embodiment, the glass core 100 may comprise a glass substrate 101. The glass substrate 101 may be any suitable glass material. For example, the glass substrate 101 may comprise E-glass, S-glass, LD-glass, L2-glass, NER-glass, or Q-glass. The glass substrate 101 may be a glass material that is suitable for laser assisted etching processes in order to form the via openings 111. Laser assisted etching processes may include exposing the glass to a laser. The laser exposure modifies a crystal structure and/or phase of the glass. The modified regions of the glass are then more susceptible to a wet etching chemistry. In some instances a double sided exposure may be used. In such an embodiment, the via openings 111 may have an hourglass shaped cross-section. An hourglass shaped cross-section may refer to a structure that has ends that are wider than a middle region, so that the structure resembles the shape of an hourglass. In an embodiment, the glass substrate 101 may have any suitable thickness. For example, the glass substrate 101 may have a thickness between approximately 50 μm and approximately 1,000 μm.

In an embodiment, vias 110 are provided in the via openings 111. The vias 110 may comprise a conductive material, such as copper. As shown, the vias 110 conform to the shape of the via openings 111. This may result in the vias 110 having an hourglass shaped cross-section as well. In an embodiment, pads 114 may be provided over and under the vias 110. Traces 115 may also be provided on the first surface 102 and the second surface 103 of the glass substrate 101.

In an embodiment, a diffusion layer 120 may be provided in the glass substrate 101. The diffusion layer 120 may be a region of the glass substrate 101 that has a relatively high concentration of a dopant or other diffusion species. The dopant or other diffusion species may not be present in the bulk of the glass substrate 101, or the concentration of the dopant or other diffusion species may be higher in the diffusion layer 120 than the remainder of the glass substrate 101. In an embodiment, the diffusion layer 120 may be selectively deposited. That is, the diffusion layer 120 may not be provided over the entirety of the first surface 102 and the second surface 103. Additionally, the diffusion layer 120 may line selected ones of the via openings 111. That is, not all via openings 111 may be lined with the diffusion layer 120.

In the particular embodiment shown in FIG. 1, the diffusion layer 120 may be a composition that locally decreases the dielectric constant. For example, the diffusion layer 120 may comprise a borate (e.g., boron and oxygen). The borate composition may account for up to approximately 20% of the total glass composition in some embodiments. High concentrations of borate may reduce the dielectric constant Dk to values of approximately 5 or less. In a particular embodiment, the localized dielectric constant Dk in the diffusion layer 120 may be approximately 4.5 or less. In an embodiment, the dielectric constant Dk in the diffusion layer 120 may be less than the dielectric constant Dk of the bulk of the glass core 101. For example, the diffusion layer 120 may have a dielectric constant Dk that is at least 1.0 smaller than the dielectric constant Dk in the bulk of the glass core 101. In some instances the dielectric constant Dk in the diffusion layer 120 may be up to 2.0 smaller than the dielectric constant Dk in the bulk of the glass core 101.

In an embodiment, the thickness of the diffusion layer 120 may be up to approximately 5 μm, or up to approximately 10 μm. The diffusion layer 120 may also demonstrate a gradient into the surface of the glass core 101. That is, a concentration of the diffusion layer 120 near the surface of the glass core 101 may be higher than a concentration of the diffusion layer 120 a distance into the glass core 101. In an embodiment, the presence of the diffusion layer 120 may be detected using material characterization processes, such as XPS, Raman spectroscopy, EDX spectroscopy, and the like.

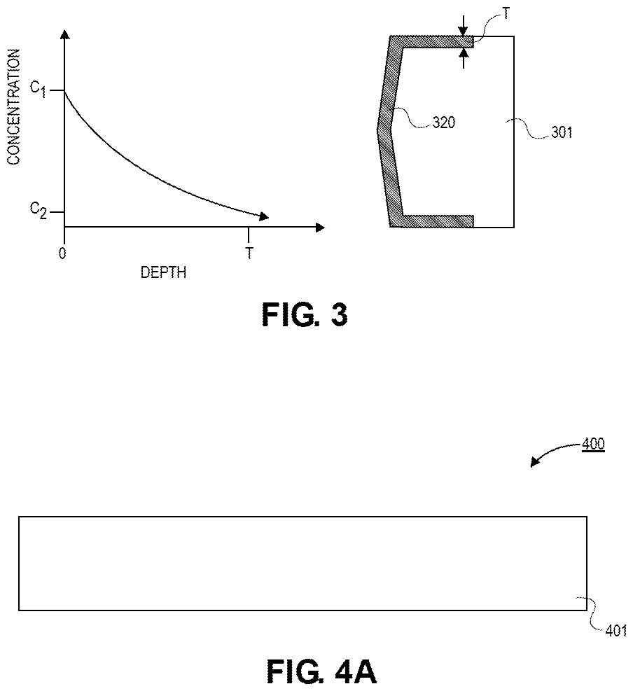

Referring now to FIG. 2, a cross-sectional illustration of a glass core 200 is shown, in accordance with an embodiment. In an embodiment, the glass core 200 may comprise a glass substrate 201. The glass substrate 201 may be any suitable glass material. For example, the glass substrate 201 may comprise E-glass, S-glass, LD-glass, L2-glass, NER-glass, or Q-glass. The glass substrate 201 may be a glass material that is suitable for laser assisted etching processes in order to form the via openings 211. In some instances a double sided exposure may be used. In such an embodiment, the via openings 211 may have an hourglass shaped cross-section. In an embodiment, the glass substrate 201 may have any suitable thickness. For example, the glass substrate 201 may have a thickness between approximately 50 μm and approximately 1,000 μm.

In an embodiment, vias 210 are provided in the via openings 211. The vias 210 may comprise a conductive material, such as copper. As shown, the vias 210 conform to the shape of the via openings 211. This may result in the vias 210 having an hourglass shaped cross-section as well. In an embodiment, pads 214 may be provided over and under the vias 210. Traces 215 may also be provided on the first surface 202 and the second surface 203 of the glass substrate 201.

In an embodiment, a diffusion layer 220 may be provided in the glass substrate 201. The diffusion layer 220 may be a region of the glass substrate 201 that has a relatively high concentration of a dopant or other diffusion species. The dopant or other diffusion species may not be present in the bulk of the glass substrate 201, or the concentration of the dopant or other diffusion species may be higher in the diffusion layer 220 than the remainder of the glass substrate 201. In an embodiment, the diffusion layer 220 may be selectively deposited. That is, the diffusion layer 220 may not be provided over the entirety of the first surface 202 and the second surface 203. Additionally, the diffusion layer 220 may line selected ones of the via openings 211. That is, not all via openings 211 may be lined with the diffusion layer 220.

In the particular embodiment shown in FIG. 2, the diffusion layer 220 may be a composition that locally increases the modulus. For example, the diffusion layer 220 may comprise alumina (e.g., aluminum and oxygen). The alumina composition may account for up to approximately 25% of the total glass composition in some embodiments. High concentrations of alumina may increase the modulus to values of approximately 80 GPa or more. In a particular embodiment, the localized modulus in the diffusion layer 220 may be approximately 85 GPa or more. In an embodiment, the modulus in the diffusion layer 220 may be greater than the modulus of the bulk of the glass core 201. For example, the diffusion layer 220 may have a modulus that is at least 10 GPa higher than the modulus in the bulk if the glass core 201. In some instances the modulus in the diffusion layer 220 may be up to 20 GPa higher than the modulus in the bulk of the glass core 201.

In an embodiment, the thickness of the diffusion layer 220 may be up to approximately 5 μm, or up to approximately 10 μm. The diffusion layer 220 may also demonstrate a gradient into the surface of the glass core 201. That is, a concentration of the diffusion layer 220 near the surface of the glass core 201 may be higher than a concentration of the diffusion layer 220 a distance into the glass core 201. In an embodiment, the presence of the diffusion layer 220 may be detected using material characterization processes, such as XPS, Raman spectroscopy, EDX spectroscopy, and the like.

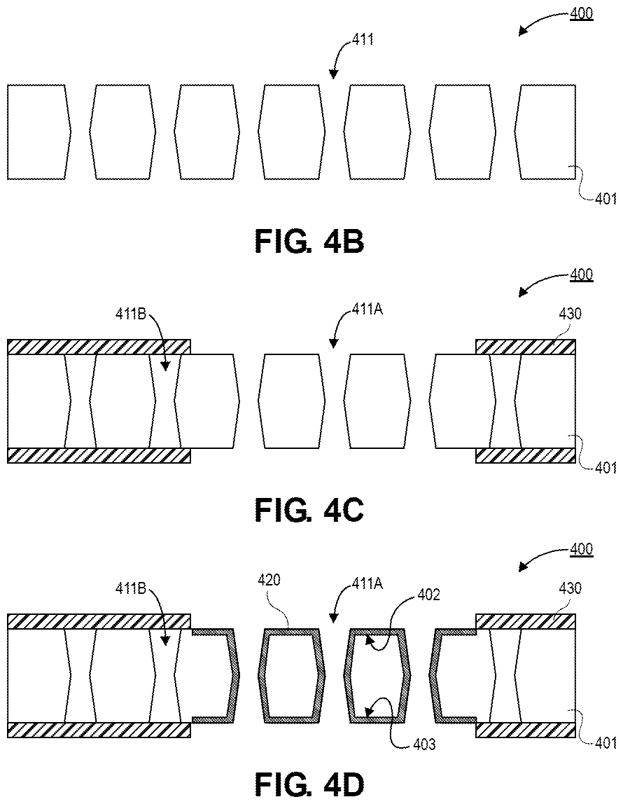

Referring now to FIG. 3, a graph of the concentration of the diffusion layer 320 with respect to depth into the surface is shown, in accordance with an embodiment. As shown, the surface (0 μm), the concentration is at a first concentration C₁. The concentration shown in FIG. 3 is the concentration of the dopant or other species used to form the diffusion layer 320. The first concentration may be up to approximately 25% of the total composition of the glass substrate 301. In an embodiment, the concentration may then decrease to a second concentration C₂ at a depth T into the thickness of the glass substrate 301. The second concentration C₂ may be above 0% in some embodiments. In other embodiments, the second concentration C₂ may be approximately 0%. The depth T may be up to approximately 5 μm or up to approximately 10 μm. While shown in the cross-sectional illustration of FIG. 3 as having a discrete end point at the depth T, it is to be appreciated that the diffusion layer 320 may not have a clear endpoint. That is, the composition of the diffusion layer 320 may continually decrease until it reaches approximately 0% in composition. The point where 0% composition is reached may not be clearly identifiable using certain material analysis compositions. Additionally, in glass substrates 301 that include the diffusing species as part of the bulk composition, the concentration of the diffusing species may not reach 0% composition. In such instances, the composition of the diffusing species in the bulk composition of the glass substrate 301 may be the minimum concentration reached by the diffusion layer 320. For example, if the bulk composition of the glass substrate 301 comprises 10% of the diffusing species, then a minimum concentration in the diffusion layer 320 may be down to approximately 10%.

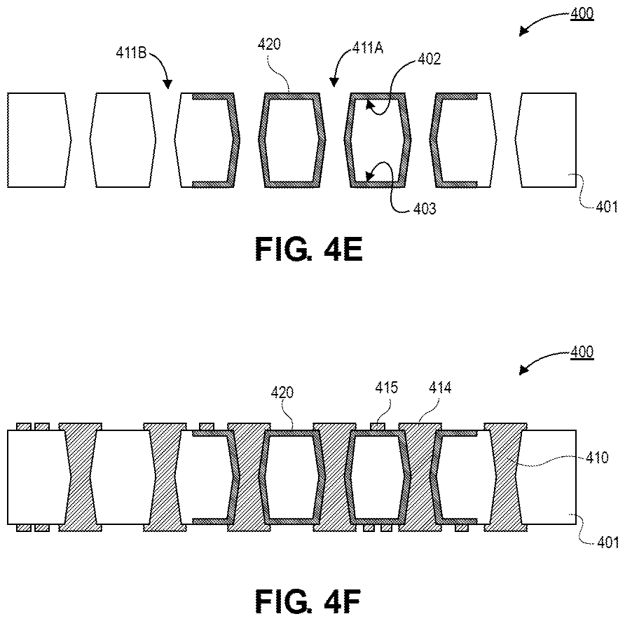

Referring now to FIGS. 4A-4F, a series of cross-sectional illustrations depicting a process for forming a glass core 400 is shown, in accordance with an embodiment. In the illustrated embodiment, the diffusion layer is shown as having the same shading as shown in FIG. 1. That is, the diffusion layer 420 may be used in order to decrease the dielectric constant Dk at the surface of the glass substrate 401. However, it is to be appreciated that substantially similar processes may be used in order to locally increase the modulus of the glass substrate 401 by using a different dopant species.

Referring now to FIG. 4A, a cross-sectional illustration of a glass core 400 at a stage of manufacture is shown, in accordance with an embodiment. As shown, a glass substrate 401 may be provided. The glass substrate 401 may include a glass that is compatible with a laser assisted patterning process. The glass substrate 401 may have any suitable glass formulation, such as E-glass, S-glass, LD-glass, L2-glass, NER-glass, or Q-glass. In an embodiment, the glass substrate 401 may have a thickness between approximately 50 μm and approximately 1,000 μm.

Referring now to FIG. 4B, a cross-sectional illustration of the glass core 400 after via openings 411 are formed is shown, in accordance with an embodiment. In an embodiment, the via openings 411 may be formed with a laser assisted patterning process. That is, a laser may be used to expose portions of the glass substrate 401 in order to modify the microstructure and/or phase of the glass substrate 401. The modified regions of the glass substrate 401 may then be etched away with a wet etching process. In some embodiments, a dual sided laser exposure process may be used. The dual sided process may result in the via openings 411 having an hourglass shaped cross-section. If a single sided laser exposure process is used, the via openings 411 may have sidewalls with a single taper that is wider at the top than at the bottom.

Referring now to FIG. 4C, a cross-sectional illustration of the glass core 400 after a resist layer 430 is deposited and patterned is shown, in accordance with an embodiment. In an embodiment, the resist layer 430 may be a dry film resist (DFR) or any other suitable resist material. The resist layer 430 may be used to cover one or more via openings 411B. The via openings 411B are via openings where there is no need to provide the diffusion layer 420 (which is added in a subsequent processing operation). For example, the via openings 411B may be provided in locations where HSIO vias are not needed. The resist layer 430 may be patterned to expose one or more via openings 411A. The exposed via openings 411A may be the locations where HSIO vias are necessary. While reference to HSIO architectures are described with respect to FIGS. 4A-4F, it is to be appreciated that other dopant species may be used in order to locally increase the modulus of the glass substrate 401 to provide more robust mechanical reliability (e.g., similar to the embodiment described above with respect to FIG. 2).

In the illustrated embodiment, a single opening in the resist layer 430 spans across several via openings 411A. However, it is to be appreciated that each via openings 411A may be exposed by discrete openings in the resist layer 430. For example, the three via openings 411A may each be exposed by different openings through the resist layer 430. Additionally, while the via openings 411A are all shown as being adjacent to each other, it is to be appreciated that one or more via openings 411B may be provided between each pair of via openings 411A. That is, the via openings 411A may be distributed across the glass substrate 401 in any layout or pattern.

Referring now to FIG. 4D, a cross-sectional illustration of the glass core 400 after a diffusion layer 420 is formed is shown, in accordance with an embodiment. In an embodiment, the diffusion layer 420 may be formed by diffusing a species into the exposed surfaces of the glass substrate 401. For example, species may be diffused into a top surface 402, a bottom surface 403, and sidewall surfaces of the via openings 411A. The diffusing species may be a species that decreases the dielectric constant Dk of the glass substrate 401. For example, a borate (e.g., boron and oxygen) may be diffused into the exposed surfaces of the glass substrate 401. In embodiments where an improved modulus is desired, a dopant species of alumina (e.g., aluminum and oxygen) may be used to form the diffusion layer 420.

In an embodiment, the diffusion layer 420 may have a thickness that is up to approximately 5 μm or up to approximately 10 μm. The diffusion layer 420 may have a concentration of the dopant that is up to approximately 25% of the total glass composition. The concentration of the dopant may follow a gradient, where the surface of the glass substrate 401 has a higher concentration of the dopant than a point of the diffusion layer 420 set in a distance from the surface of the glass substrate 401.

In an embodiment, the diffusion layer 420 may be formed with any suitable diffusion process. In one example, an ion implantation process may be used to implant dopants into the surface of the glass substrate 401. The ion implantation process may be used in conjunction with an anneal in order to drive diffusion of the implanted species. In other embodiments, a heat treatment or chemical treatment may be used in order to drive diffusion of the dopant into the surface of the glass substrate 401.

Referring now to FIG. 4E, a cross-sectional illustration of the glass core 400 after the resist layer 430 is removed is shown, in accordance with an embodiment. In an embodiment, the resist layer 430 may be removed with a resist stripping process, an etching process, or the like. As shown, removal of the resist layer 430 re-exposes the via openings 411B. Since the diffusion layer 420 is formed into the surfaces of the glass substrate 401, the via openings 411A may be substantially unaltered. This may result in the via openings 411A being substantially similar to the via openings 411B. The only difference is the presence of the diffusion layer 420 into the surface of the glass substrate 401.

Referring now to FIG. 4F, a cross-sectional illustration of the glass core 400 after vias 410 are formed is shown, in accordance with an embodiment. In an embodiment, the vias 410 may be formed with any suitable plating process, such as electroless plating, electrolytic plating, or the like. The vias 410 may be any suitable conductive material or materials, such as copper or the like. In an embodiment, the vias 410 may be in direct contact with the diffusion layer 420. In embodiments with localized reduction in the dielectric constant Dk, the vias 410 may be suitable for HSIO applications that require low loss materials.

In an embodiment, pads 414 may be provided over and under the vias 410. The pads 414 may be formed with a plating process similar to the plating process used to form the vias 410. In some instances, the vias 410 and the pads 414 may be plated with the same plating process. Additionally, one or more traces 415 may be provided on the top and bottom of the glass core 401. The traces 415 may be provided between the pads 414 in some embodiments. In some instances, traces 415 may be provided directly over the diffusion layer 420. However, traces 415 may also be formed over the glass substrate 401 in locations where the diffusion layer 420 is not present. After the formation of the glass core 400 shown in FIG. 4F, buildup layers and the like may be formed over and under the glass core 400 using standard fabrication processes in order to provide a cored electronic package.

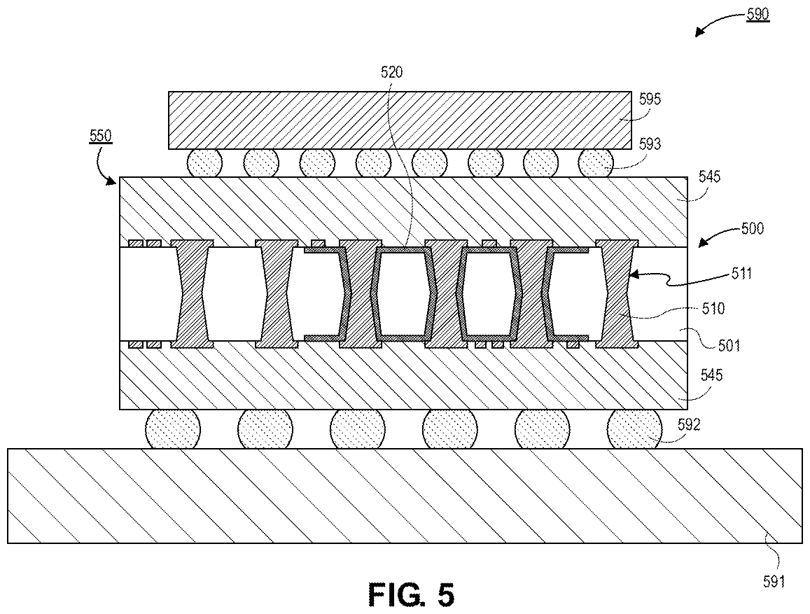

Referring now to FIG. 5, a cross-sectional illustration of an electronic system 590 is shown, in accordance with an embodiment. In an embodiment, the electronic system 590 may comprise a board 591, such as a printed circuit board (PCB). The board 591 may be coupled to a package substrate 550 by interconnects 592. While shown as solder interconnects 592, it is to be appreciated that any interconnect architecture may be used for the interconnects 592.

In an embodiment, a die 595 may be coupled to the package substrate 550. The die 595 may be coupled to the package substrate 550 using first level interconnect (FLI) architectures such as solder interconnects 593, copper bumps, hybrid bonding, or the like. In an embodiment, the die 595 may be a compute die, such as a processor, a graphics processor, a system on a chip (SoC), an ASIC, or the like. More than one die 595 may also be coupled to the package substrate 550 in some embodiments. Additional dies may include memory dies or any other type of die.

In an embodiment, the package substrate 550 may comprise a glass core 500 with buildup layers 545 over and under the glass core 500. The glass core 500 may include a glass substrate 501. The glass substrate 501 may have a thickness that is between approximately 50 μm and approximately 1,000 μm. The glass substrate 501 may be a glass material that is compatible with laser assisted patterning processes. In an embodiment, vias 510 may be provided through via openings 511 in the glass substrate 501. The vias 510 may have hourglass shaped cross-sections in some embodiments.

In an embodiment, portions of the glass core 500 may include a diffusion layer 520. The diffusion layer 520 may comprise a dopant that is used to locally modify mechanical or electrical properties of the glass substrate 501. For example, the glass substrate 501 may be modified to have a lower dielectric constant Dk or a higher modulus. Lower dielectric constants may be obtained by using a dopant such as borate (e.g., boron and oxygen), and higher moduli may be obtained by using a dopant such as alumina (e.g., aluminum and oxygen). In some embodiments the dopant concentration may be up to approximately 25% of the overall composition of the glass substrate 501. In an embodiment, the diffusion layer 520 may be provided on the surface of the via openings 511 and over the top and bottom surface of the glass substrate 501. The diffusion layer 520 may have a thickness that is up to approximately 5 μm or approximately 10 μm.

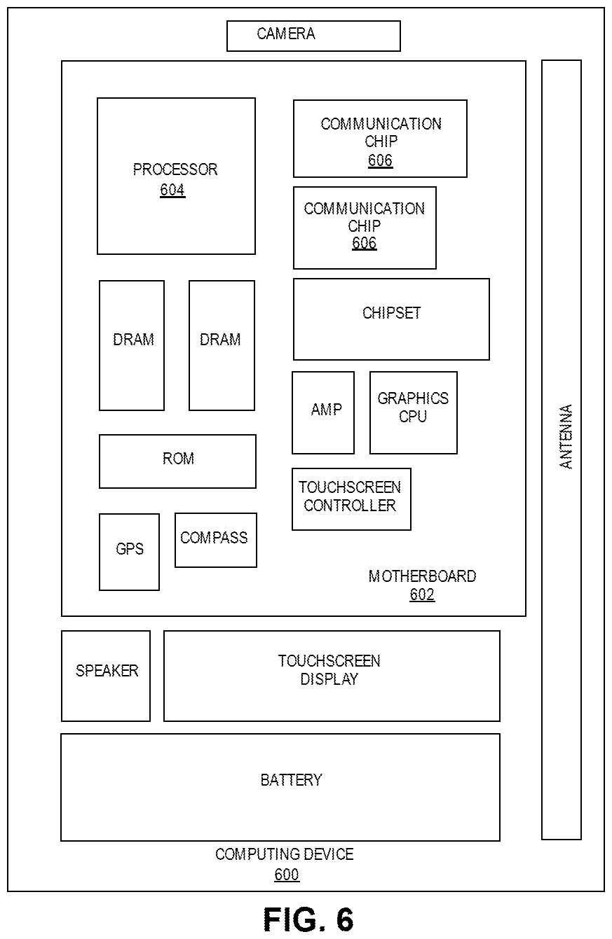

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be coupled to a package substrate that includes a glass core that has a localized diffusion layer in order to modify electrical or mechanical properties of the glass core, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be coupled to a package substrate that includes a glass core that has a localized diffusion layer in order to modify electrical or mechanical properties of the glass core, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a core for an electronic package, comprising: a substrate with a first surface and a second surface opposite from the first surface, wherein the substrate comprises glass; a via opening through the substrate; and a diffusion layer along the first surface, the second surface, and the via opening.

Example 2: the core of Example 1, wherein the diffusion layer comprises boron and oxygen.

Example 3: the core of Example 2, wherein the diffusion layer has a dielectric constant that is lower than a dielectric constant of a bulk of the substrate.

Example 4: the core of Example 1, wherein the diffusion layer comprises aluminum and oxygen.

Example 5: the core of Example 4, wherein the diffusion layer has a modulus that is greater than a modulus of a bulk of the substrate.

Example 6: the core of Examples 1-5, wherein the diffusion layer has a first concentration at a surface of the substrate and a second concentration a distance away from the surface of the substrate, wherein the second concentration is less than the first concentration.

Example 7: the core of Example 6, wherein the distance away from the surface of the substrate is approximately 5 μm or less.

Example 8: the core of Examples 1-7, wherein the diffusion layer is omitted from select portions of the first surface and the second surface.

Example 9: the core of Example 8, further comprising: a second via opening through the substrate, wherein the second via opening is not lined by the diffusion layer.

Example 10: the core of Examples 1-9, further comprising: a conductive via in the via opening.

Example 11: the core of Examples 1-10, wherein the via opening has tapered sidewalls.

Example 12: the core of Examples 1-11, wherein a thickness of the substrate is between approximately 50 μm and approximately 1,000 μm.

Example 13: the core of Examples 1-12, wherein the substrate comprises E-glass, S-glass, LD-glass, L2-glass, NER-glass, or Q-glass.

Example 14: a method of forming a core, comprising: forming a plurality of via openings through a substrate; masking portions of the substrate with a resist layer, wherein one or more via openings are exposed by an opening in the resist layer; forming a doped layer into surfaces of the substrate that are exposed by the opening in the resist layer; removing the resist layer; diffusing the doped layer with a heat treatment to form a diffusion layer; and forming vias in the via openings.

Example 15: the method of Example 14, wherein the via openings are formed with a laser assisted etching process.

Example 16: the method of Examples 14-15, wherein the diffusion layer comprises boron and oxygen.

Example 17: the method of Examples 14-16, wherein the diffusion layer comprises aluminum and oxygen.

Example 18: the method of Examples 14-17, wherein the substrate has a thickness that is between approximately 50 μm and approximately 1,000 μm.

Example 19: the method of Examples 14-18, wherein the diffusion layer has a thickness of approximately 5 μm or less.

Example 20: the method of Examples 14-19, wherein the diffusion layer is formed into a top surface and a bottom surface of the substrate.

Example 21: the method of Examples 14-20, wherein the via openings have tapered sidewalls.

Example 22: a computing system, comprising: a board; a package substrate coupled to the board, wherein the package substrate comprises: a core, wherein the core comprises glass; via openings through the core; and a diffusion layer that extends into surfaces of the core including a top surface, a bottom surface, and sidewall surfaces of the via openings; and a die coupled to the package substrate.

Example 23: the computing system of Example 22, wherein the diffusion layer comprises boron and oxygen.

Example 24: the computing system of Example 22, wherein the diffusion layer comprises aluminum and oxygen.

Example 25: the computing system of Examples 22-24, wherein a thickness of the diffusion layer is up to approximately 5 μm.

What is claimed is:

1. A core for an electronic package, comprising:
a substrate with a first surface and a second surface opposite from the first surface, wherein the substrate comprises glass;
a via opening through the substrate; and
a diffusion layer along the first surface, the second surface, and the via opening.

2. The core of claim 1, wherein the diffusion layer comprises boron and oxygen.

3. The core of claim 2, wherein the diffusion layer has a dielectric constant that is lower than a dielectric constant of a bulk of the substrate.

4. The core of claim 1, wherein the diffusion layer comprises aluminum and oxygen.

5. The core of claim 4, wherein the diffusion layer has a modulus that is greater than a modulus of a bulk of the substrate.

6. The core of claim 1, wherein the diffusion layer has a first concentration at a surface of the substrate and a second concentration a distance away from the surface of the substrate, wherein the second concentration is less than the first concentration.

7. The core of claim 6, wherein the distance away from the surface of the substrate is approximately 5 μm or less.

8. The core of claim 1, wherein the diffusion layer is omitted from select portions of the first surface and the second surface.

9. The core of claim 8, further comprising:
a second via opening through the substrate, wherein the second via opening is not lined by the diffusion layer.

10. The core of claim 1, further comprising:
a conductive via in the via opening.

11. The core of claim 1, wherein the via opening has tapered sidewalls.

12. The core of claim 1, wherein a thickness of the substrate is between approximately 50 μm and approximately 1,000 μm.

13. The core of claim 1, wherein the substrate comprises E-glass, S-glass, LD-glass, L2-glass, NER-glass, or Q-glass.

14. A method of forming a core, comprising:
forming a plurality of via openings through a substrate;
masking portions of the substrate with a resist layer, wherein one or more via openings are exposed by an opening in the resist layer;
forming a doped layer into surfaces of the substrate that are exposed by the opening in the resist layer;
removing the resist layer;
diffusing the doped layer with a heat treatment to form a diffusion layer; and
forming vias in the via openings.

15. The method of claim 14, wherein the via openings are formed with a laser assisted etching process.

16. The method of claim 14, wherein the diffusion layer comprises boron and oxygen.

17. The method of claim 14, wherein the diffusion layer comprises aluminum and oxygen.

18. The method of claim 14, wherein the substrate has a thickness that is between approximately 50 μm and approximately 1,000 μm.

19. The method of claim 14, wherein the diffusion layer has a thickness of approximately 5 μm or less.

20. The method of claim 14, wherein the diffusion layer is formed into a top surface and a bottom surface of the substrate.

21. The method of claim 14, wherein the via openings have tapered sidewalls.

22. A computing system, comprising:
a board;
a package substrate coupled to the board, wherein the package substrate comprises:
a core, wherein the core comprises glass;
via openings through the core; and
a diffusion layer that extends into surfaces of the core including a top surface, a bottom surface, and sidewall surfaces of the via openings; and
a die coupled to the package substrate.

23. The computing system of claim 22, wherein the diffusion layer comprises boron and oxygen.

24. The computing system of claim 22, wherein the diffusion layer comprises aluminum and oxygen.

25. The computing system of claim 22, wherein a thickness of the diffusion layer is up to approximately 5 μm.
